(19) United States
(12) Patent Application Publication
(10) Pub. No.: US 2015/0295489 A1
(43) Pub. Date: Oct. 15, 2015

(54) SEMICONDUCTOR DEVICE

(71) Applicant: Makoto IMAI, Toyota-shi, Aichi (JP)

(72) Inventor: Makoto Imai, Toyota-shi (JP)

(73) Assignee: TOYOTA JIDOSHA KABUSHIKI KAISHA, Toyota-shi, Aichi-ken (JP)

(21) Appl. No.: 14/443,532

(22) PCT Filed: Dec. 25, 2012
(86) PCT No.: PCT/JP2012/083466

§ 371 Date: May 18, 2015

(51) Int. Cl. H02M 1/32; H02M 3/337; H01L 23/528; H01L 27/06; H01L 23/525

(52) U.S. Cl. CPC H02M 1/32; H01L 27/0629; H01L 23/5256; H01L 23/528; H02M 3/337; H02M 2001/325

(57) ABSTRACT

A semiconductor device presented herein includes a first wiring including a first end and a second end configured to receive a voltage lower than a voltage of the first end. The semiconductor device includes a second wiring including a third end connected to the first end, and a fourth end connected to the second end. The semiconductor device includes a switching element set on the first wiring, a capacitor set on the second wiring, and a fuse portion set on the second wiring and positioned on a third end side of the capacitor. The semiconductor device includes a potential sensing portion connected to the second wiring between the fuse portion and the capacitor and configured to sense a potential of a connection point thereof.

### TECHNICAL FIELD

A technology disclosed herein relates o semiconductor devices.

### BACKGROUND ART

In a semiconductor device including a semiconductor element such as a switching element or a diode, a capacitor may be provided in parallel to the semiconductor element. The capacitor for example achieves a reduction in a surge voltage that is applied to the semiconductor element. However, in such semiconductor devices, a capacitor failure caused by short-circuiting may cause an overcurrent to flow through a wiring on which the capacitor is set. Japanese Patent Application Publication No. H1-103163 A discloses a semiconductor device in which a capacitor is provided in parallel to a diode. In this semiconductor device, a fuse portion (blowout pattern) is provided as a part of a junction electrode pattern of the capacitor. When the capacitor fails by short-circuiting, the fuse portion blows out to break off a conduction path. This makes it possible to reduce the risk of the overcurrent flowing through the wiring.

### SUMMARY OF INVENTION

### Technical Problem

However, when the fuse portion has blown out to break off the conduction path, the conventional technology cannot sense the break-off of the conduction path. For this reason, for example, if the conventional technology is applied to a semiconductor device including a switching element, the switching element may continue to operate even after the capacitor has lost the effect of reducing the surge voltage. This may result in application of an excessive surge voltage to the switching element.

The present specification provides a technology, in a semiconductor device including a wiring in which a capacitor and a fuse portion are set on a conduction path, which can sense a blowout of the fuse portion.

### Solution to Technical Problem

A semiconductor device disclosed herein, comprises a first wiring including a first end and a second end configured to receive a voltage lower than a voltage of the first end. The semiconductor device comprises a second wiring including a third end connected to the first end, and a fourth end connected to the second end. The semiconductor device comprises a switching element set on the first wiring. The semiconductor device comprises a capacitor set on the second wiring. The semiconductor device comprises a fuse portion set on the second wiring and positioned on a third end side of the capacitor. The semiconductor device comprises a potential sensing portion connected to the second wiring between the fuse portion and the capacitor and configured to sense a potential of a connection point thereof.

In the semiconductor device described above, the fuse portion is set on a high-potential side of the capacitor, and the second wiring and the potential sensing portion are connected at a position between the capacitor and the fuse portion. For this reason, a blowout of the fuse portion causes a potential sensed by the potential sensing portion to drop. This enables the potential sensing portion to sense the blowout of the fuse portion.

### BRIEF DESCRIPTION OF DRAWINGS

FIG. 1 is a circuit diagram showing a DC-DC converter 2 of Embodiment 1.

FIG. 2 is a cross-sectional view showing a capacitor-sealing body 90 of Embodiment 1.

FIG. 3 is a perspective view showing a capacitor element 180 of Embodiment 1.

FIG. 4 is a graph showing a relationship between a target voltage signal S_{TG} and an output voltage V_{OUT} of the DC-DC converter 2 of Embodiment 1.

FIG. 5 is a circuit diagram showing a DC-DC converter 202 of Embodiment 2.

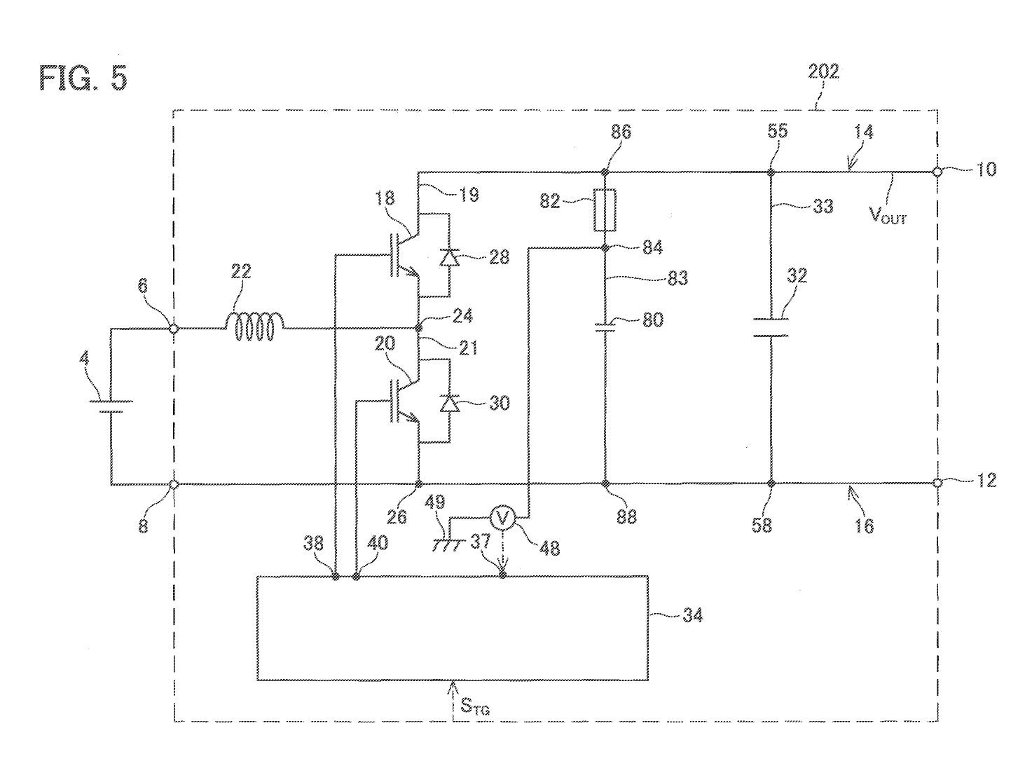

### DESCRIPTION OF EMBODIMENTS

Some of the technical features of embodiments disclosed herein are described below. It should be noted that matters described below each independently have technical utility.

(Feature 1) A semiconductor device disclosed herein may further comprise a control device configured to reduce a current flowing through the switching element when the second wiring is determined, from the potential sensed by the potential sensing portion, to have broken off.

In the semiconductor device described above, the current flowing through the switching element is reduced when it is determined that the fuse portion has blown out, and the effect of reducing a surge voltage in the capacitor can no longer be enjoyed. This allows the current to flow through the switching element while reducing the surge voltage that is applied to the switching element.

(Feature 2) A semiconductor device disclosed herein may be configured to receive an input voltage between an input terminal and an input-side reference terminal and to output an output voltage from between an output terminal and an output-side reference terminal. The semiconductor device may comprise an input/output line connecting the input terminal and the output terminal. The semiconductor device may comprise a reference potential line connecting the input-side reference terminal and the output-side reference terminal. The semiconductor device may comprise a first switching element set on the input/output line. The semiconductor device may comprise a reactor set on the input/output line and positioned on an input terminal side of the first switching element. The semiconductor device may comprise a third wiring connecting a first connection point and a second connection point, the first connection point being set on the input/output line and positioned between the reactor and the first switching element, and the second connection point being positioned on the reference potential line. The semiconductor device may comprise a second switching element set on the third wiring. The semiconductor device may comprise a fourth wiring connected in parallel to one of the first switching element and the second switching element. The semiconductor device may comprise a first capacitor set on the fourth wiring. The semiconductor device may comprise a first fuse portion set on the fourth wiring and positioned on a high potential side of the first capacitor. The semiconductor device may comprise a potential sensing portion connected to the fourth wiring between the first fuse portion and the first capacitor, and configured to sense a potential of a connection point thereof.

In the semiconductor device described above, the first fuse portion is set on a high-potential side of the first capacitor, and the fourth wiring and the potential sensing portion are connected in a position between the first capacitor and the first fuse portion. For this reason, a blowout of the first fuse portion causes a fall in a potential that is sensed by the potential sensing portion. This makes it possible to sense the blowout of the first fuse portion.

(Feature 3) The input/output line may include a third connection point positioned on an output terminal side of the first switching element, and the fourth wiring may connect the third connection point and the first connection point.

In the semiconductor device described above, the blowout of the first fuse portion set on a high-potential side of the first capacitor connected in parallel to the first switching element causes the potential sensed by the potential sensing portion to drop. This makes it possible to sense the blowout of the first fuse portion.

(Feature 4) The reference potential line may include a fourth connection point positioned on an output-side reference terminal side of the second connection point, and the fourth wiring may connect the first connection point and the fourth connection point.

In the semiconductor device described above, the blowout of the first fuse portion set on the high-potential side of the first capacitor connected in parallel to the second switching element causes the potential sensed by the potential sensing portion to drop. This makes it possible to sense the blowout of the first fuse portion.

(Feature 5) The input/output line may include a fifth connection point positioned on an output terminal side of the first switching element, the reference potential line may include a sixth connection point positioned on an output-side reference terminal side of the second connection point, and the fourth wiring may connect the fifth connection point and the sixth connection point.

In the semiconductor device described above, the first capacitor is connected in parallel to the first switching element and the second switching element. The blowout of the first fuse portion set on the high-potential side of the first capacitor causes the potential sensed by the potential sensing portion to drop. This makes it possible to sense the blowout of the first fuse portion.

(Feature 6) A semiconductor device disclosed herein may further comprise a control device configured to reduce a current flowing through a switching element connected in parallel to the fourth wiring when the fourth wiring is determined, from the potential sensed by the potential sensing portion, to have broken off.

In the semiconductor device described above, the current flowing through the switching element set in parallel to the fourth wiring is reduced when it is determined that the first fuse portion has blown out, and the fourth wiring has been broken off thereby. This allows the current to flow through the switching element while reducing the surge voltage that is applied to the switching element.

### Embodiment 1

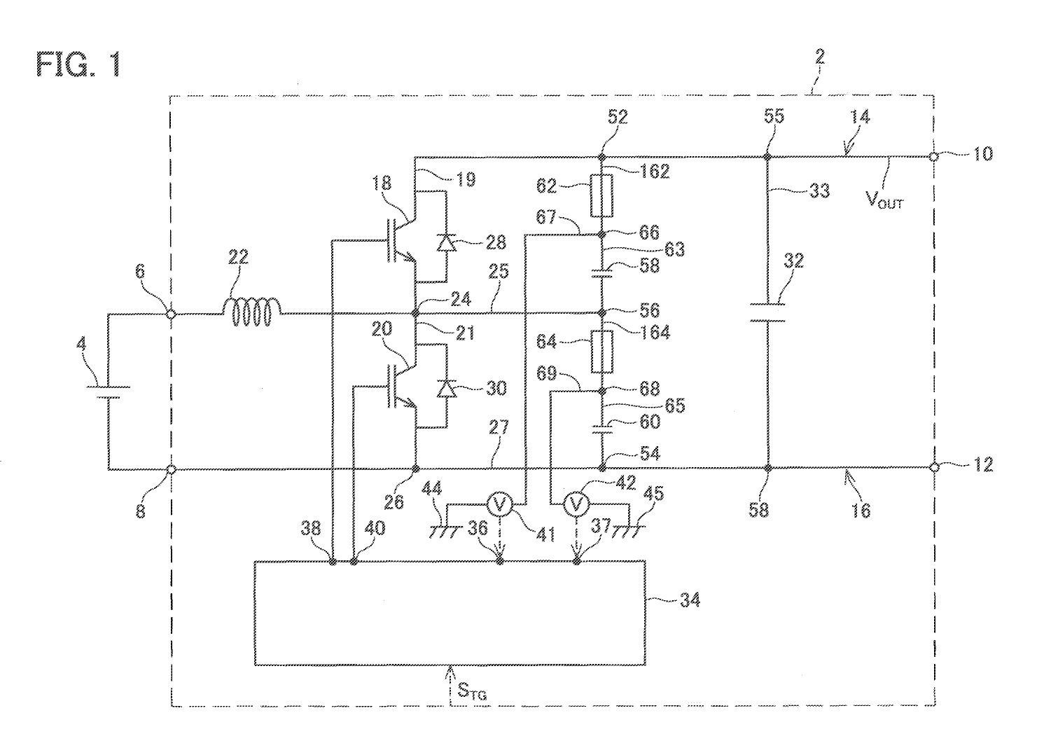

A DC-DC converter 2 raises an input voltage inputted from a battery 4. As shown in FIG. 1, the DC-DC converter 2 outputs an output voltage to a load (not illustrated). The load is for example an inverter (not illustrated) or the like.

A configuration of the DC-DC converter 2 of the present embodiment is described below. The DC-DC converter 2 includes an input terminal 6 and an input-side reference terminal 8. The input terminal 6 is connected to a positive electrode of the battery 4. The input-side reference terminal 8 is connected to a negative electrode of the battery 4. That is, an input voltage is inputted between the input terminal 6 and the input-side reference terminal 8. Further, the input-side reference terminal 8 is connected to the ground. The DC-DC converter 2 includes an output terminal 10 and an output-side reference terminal 12. The output terminal 10 is connected, for example, to an input terminal (not illustrated) on a positive electrode side of the inverter. The output-side reference terminal 12 is connected, for example, to an input terminal (not illustrated) on a negative electrode side of the inverter. That is, an output voltage V_{OUT} is outputted from between the output terminal 10 and the output-side reference terminal 12.

The DC-DC converter 2 includes an input/output line 14 and a reference potential line 16. Further, the DC-DC converter 2 includes a first switching element 18, a reactor 22, and a second switching element 20. The input/output line 14 connects the input terminal 6 and the output terminal 10. The reference potential line 16 connects the input-side reference terminal 8 and the output-side reference terminal 12. The first switching element 18 and the reactor 22 are set on the input/output line 14. The reactor 22 is positioned on an input terminal 6 side of the first switching element 18. A connection point 24 is provided between the reactor 22 and the first switching element 18. A connection point 26 is provided on the reference potential line 16. The connection point 24 and the connection point 26 are connected by a wiring 21. The second switching element 20 is set on the wiring 21. Usable examples of the first switching element 18 and the second switching element 20 include MOSFETs, IGBTs, etc. A free-wheeling diode 28 is set in parallel to the first switching element 18. A free-wheeling diode 30 is set in parallel to the second switching element 20.

A connection point 55 on the input/output line 14 and a connection point 58 on the reference potential line 16 are connected by a wiring 33. The connection point 55 is positioned on an output terminal 10 side of the first switching element 18 and of a connection point 52 described below. The connection point 58 is positioned on an output-side reference terminal 12 side of the connection point 26 and of a connection point 54 described below. A smoothing capacitor 32 is set on the wiring 33.

The DC-DC converter 2 includes a control device 34. The control device 34 has a terminal 38 connected to a gate of the first switching element 18. The control device 34 has a terminal 40 connected to a gate of the second switching element 20. The control device 34 changes a gate voltage of the first switching element 18 and thereby switches the first switching element 18 on and off. The control device 34 changes a gate voltage of the second switching element 20 and thereby switches the second switching element 20 on and off.

The connection point 52 is set on the input/output line 14. The connection point 52 is positioned on an output terminal 10 side of the first switching element 18. Further, the connection point 52 is positioned between the first switching element 18 and the aforementioned connection point 55. The connection point 24 and the connection point 52, which are on the aforementioned input/output line 14, are connected via a connection point 56. That is, a wiring 25 connects the connection point 24 and the connection point 56, and a wiring 63 connects the connection point 56 and the connection point 52. The wiring 63 is set in parallel to the first switching element 18. A capacitor 58 is set on the wiring 63. In other words, the capacitor 58 is set in parallel to the first switching element 18. It should be noted that a part of the input/output line 14 is hereinafter sometimes referred to as a wiring 19. The wiring 19 is a part between the connection point 52 and the connection point 24.

The connection point 54 is provided on the reference potential line 16. The connection point 54 is positioned on an output-side reference terminal 12 side of the connection point 26. Further, the connection point 54 is positioned between the connection point 26 and the aforementioned connection point 58. The aforementioned connection point 24 and the connection point 54 are connected via the connection point 56. That is, the wiring 25 connects the connection point 24 and the connection point 56 as mentioned above, and a wiring 65 connects the connection point 56 and the connection point 54. The wiring 65 is set in parallel to the second switching element 20. A capacitor 60 is set on the wiring 65. In other words, the capacitor 60 is set in parallel to the second switching element 20.

A fuse portion 62 is provided on the wiring 63. The fuse portion 62 is positioned on a connection point 52 side of the capacitor 58. A connection point 66 is provided between the fuse portion 62 and the capacitor 58. The DC-DC converter 2 includes a potential sensing portion 41. The potential sensing portion 41 is specifically a voltmeter. The potential sensing portion 41 is connected to the connection point 66. The potential sensing portion 41 senses a potential difference between a reference voltage terminal 44 to which a predetermined reference voltage (specifically, a ground potential) is applied and the connection point 66. This allows the potential sensing portion 41 to sense a potential of the connection point 66. The potential sensing portion 41 outputs a signal corresponding to the potential of the connection point 66. The signal is inputted to the control device 34 via a terminal 36 of the control device 34. It should be noted that a part of the wiring 63 is hereinafter sometimes referred to as a wiring 162. The wiring 162 is a part between the connection point 52 and the connection point 66.

Similarly, a fuse portion 64 is provided on the wiring 65. The fuse portion 64 is positioned on a connection point 56 side of the capacitor 60. A connection point 68 is provided between the fuse portion 64 and the capacitor 60. The DC-DC converter 2 includes a potential sensing portion 42. The potential sensing portion 42 is specifically a voltmeter. The potential sensing portion 42 is connected to the connection point 68. Specifically, the potential sensing portion 42 senses a potential difference between a reference voltage terminal 45 to which a predetermined reference voltage (specifically, a ground potential) is applied and the connection point 68. This allows the potential sensing portion 42 to sense a potential of the connection point 68. The potential sensing portion 42 outputs a signal corresponding to the potential of the connection point 68. The signal is inputted to the control device 34 via a terminal 37 of the control device 34.

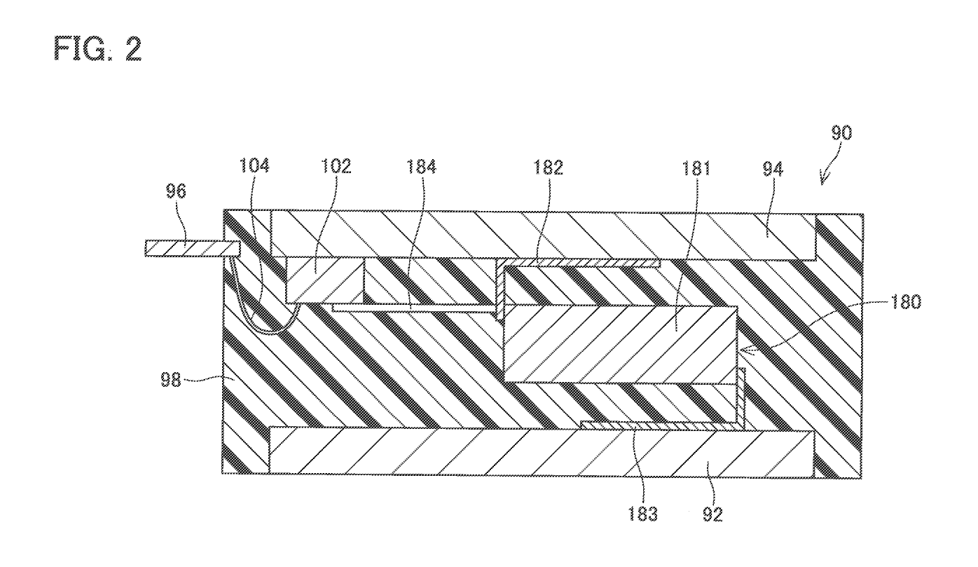

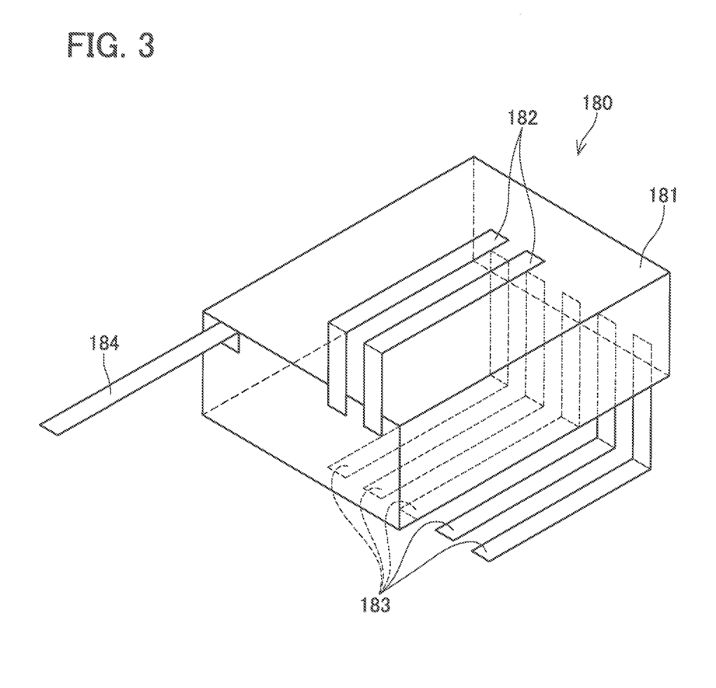

Next, a structure of a capacitor-sealing body 90 (see FIGS. 2 and 3) for the capacitors 58 and 60 of the aforementioned DC-DC converter 2 is described. As shown in FIG. 2, the capacitor-sealing body 90 includes a capacitor element 180, a source-side electrode 92, a drain-side electrode 94, and a voltage monitor terminal 96.

The drain-side electrode 94 is positioned at the top end of the capacitor-sealing body 90. The upper surface of the drain-side electrode 94 is exposed from a molded resin 98. The source-side electrode 92 is positioned at the bottom end of the capacitor-sealing body 90. The lower surface of the source-side electrode 92 is exposed from the molded resin 98.

An area around the edge of the capacitor element 180 is sealed by the molded resin 98. A usable example of the capacitor element 180 is a ceramic capacitor. As shown in FIG. 3, the capacitor element 180 includes a body portion 181, a terminal 182, and a terminal 183. The terminal 182 of the capacitor element 180 extends from an upper left (as shown in FIG. 3) end of the capacitor element 180 to the outside (specifically, to the upper side of FIG. 3) of the capacitor element 180. The terminal 182 has an end connected to the drain-side electrode 94. The terminal 183 of the capacitor element 180 extends from a lower right (as shown in FIG. 3) end of the capacitor element 180 to the outside (specifically, to the lower side of FIG. 3) of the capacitor element 180. The terminal 183 has an end connected to the source-side electrode 92.

The capacitor element 180 has a pair of electrodes (not illustrated) inside the body portion 181. One of the pair of electrodes is connected to the terminal 183 inside the capacitor element 180. The other of the pair of electrodes is connected to the terminal 182 and a terminal 184 described below inside the capacitor element 180.

The capacitor element 180 further includes the terminal 184. The terminal 184 extends from an upper left (as shown in FIG. 3) end of the capacitor element 180 to the outside (specifically, to the left side of FIG. 3) of the capacitor element 180. A connection plate 102 is set on a lower surface of the aforementioned drain-side electrode 94. The terminal 184 has an end connected to the connection plate 102. A wiring 104 connects the connection plate 102 and the voltage monitor terminal 96. A part of the voltage monitor terminal 96 that is shown on the left side of FIG. 2 is exposed on an outer side of the molded resin 98. It should be noted that the terminal 184 of the capacitor element 180 is also connected to the drain-side electrode 94 via the connection plate 102.

As shown in FIG. 3, the terminal 183 is constituted by five strip conductors. Meanwhile, the terminal 182 of the capacitor element 180 is constituted by two strip conductors. For this reason, the total of the cross-sectional areas of each conductor of the terminal 182 is smaller than the total of the cross-sectional areas of each conductor of the terminal 183. For this reason, the flow of an overcurrent through the capacitor element 180, for example, due to a failure of the capacitor element 180 caused by short-circuiting causes the terminal 182 to blow out. Further, the terminal 184 is constituted by one strip conductor.

Correspondence between each component of the capacitor-sealing body 90 and that shown in FIG. 1 is described. First, a case is described where the capacitor-sealing body 90 is used as the capacitor 58, the fuse portion 62, and the wiring 67 of FIG. 1. The drain-side electrode 94 corresponds to the connection point 52 of FIG. 1. The drain-side electrode 94 is connected to a drain electrode of the first switching element 18. The source-side electrode 92 corresponds to the connection point 56 of FIG. 1. The source-side electrode 92 is connected to a source electrode of the first switching element 18. The capacitor element 180 corresponds to the capacitor 58 of FIG. 1. The terminal 182 corresponds to the wiring 162 of FIG. 1. As mentioned above, the terminal 182 blows out in response to the overcurrent. As such, the terminal 182 also corresponds to the fuse portion 62 of FIG. 1. The terminal 184 corresponds to the wiring 67 of FIG. 1. The terminal 184 is connected to the potential sensing portion 41. A part where the terminal 184 and the capacitor element 180 have contact with each other corresponds to the connection point 66. The terminal 183 corresponds to a wiring between the capacitor 58 and the connection point 56.

Next, a case is described where the capacitor-sealing body 90 is used as the capacitor 60, the fuse portion 64, and the wiring 69. The drain-side electrode 94 corresponds to the connection point 56 of FIG. 1. The drain-side electrode 94 is connected to a drain electrode of the second switching element 20. The source-side electrode 92 corresponds to the connection point 54 of FIG. 1. The source-side electrode 92 is connected to a source electrode of the second switching element 20. The capacitor element 180 corresponds to the capacitor 60 of FIG. 1. Further, the terminal 182 corresponds to the wiring 164 of FIG. 1. The terminal 182 corresponds to the fuse portion 64 of FIG. 1. The terminal 184 corresponds to the wiring 69 of FIG. 1. The terminal 184 is connected to the potential sensing portion 42. The terminal 183 corresponds to a wiring between the capacitor 60 and the connection point 54.

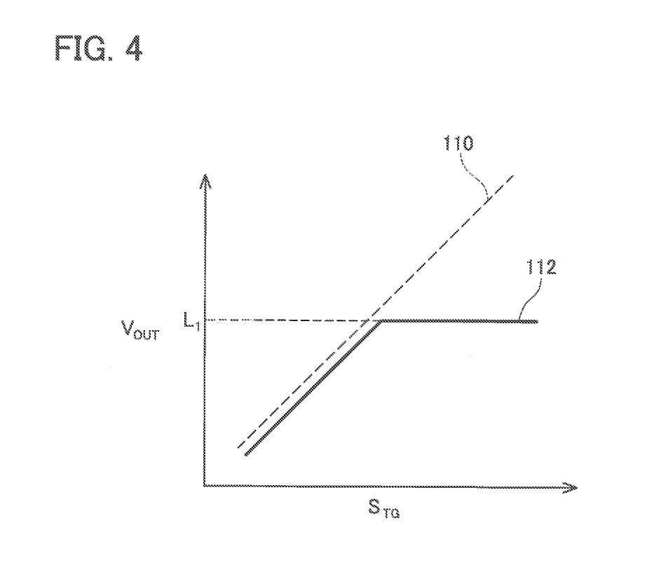

Next, operation of the DC-DC converter 2 of the present embodiment is described. The control device 34 of the DC-DC converter 2 receives a target voltage signal S_{TG} from a driving control apparatus (not illustrated). The DC-DC converter 2 outputs the output voltage V_{OUT} corresponding to the received target voltage signal S_{TG}. The broken line of the graph shown in FIG. 4 represents a standard mode characteristic 110. The standard mode characteristic 110 shows a relationship between the level of the target voltage signal S_{TG} and the magnitude of the output voltage V_{OUT} in a normal state, i.e. a state in which a blowout of the fuse portion 62 or 64 has not been sensed. In the standard mode characteristic 110, the level of the target voltage signal S_{TG} and the magnitude of the output voltage V_{OUT} are proportional to each other. Specifically, the DC-DC converter 2 controls the output voltage V_{OUT} through PWM control. The DC-DC converter 2 adjusts a duty ratio with the first switching element 18 and the second switching element 20 so that the output voltage V_{OUT} takes on a value corresponding to the target voltage signal S_{TG}. It should be noted that the solid line of the graph shown in FIG. 4 represents a protection mode characteristic 112. The protection mode characteristic 112 will be described in detail later.

When the DC-DC converter 2 operates, the control device 34 alternately turns the first switching element 18 and the second switching element 20 on and off. When the first switching element 18 is turned off and the second switching element 20 is turned on, a current flows through the reactor 22. When the first switching element 18 is turned on and the second switching element 20 is turned off, the current flowing through the reactor 22 is reduced. This causes a counter electromotive force to be generated in the reactor 22. The counter electromotive force is generated in such a direction as to suppress a reduction in the current flowing through the reactor 22 (i.e. in such a direction as to cause a current to flow from the input terminal 6 toward the output terminal 10). This causes a potential of the output terminal 10 to rise. This causes a voltage between the output terminal 10 and the output-side reference terminal 12 to be raised.

In the DC-DC converter 2 of the present embodiment, as mentioned above, the capacitor 58 is set in parallel to the first switching element 18. This reduces a surge voltage that is applied, when the first switching element 18 is turned on or off. Similarly, the capacitor 60 is set in parallel to the second switching element 20. This reduces a surge voltage that is applied when the second switching element 20 is turned on or off.

At the time of a short-circuiting failure of the capacitor 58, the fuse portion 62 blows out to break off the wiring 63. At the time of a short-circuiting failure of the capacitor 60, the fuse portion 64 blows out to break off the wiring 65. This reduces the risk of an overcurrent flowing through the DC-DC converter 2 at the time of the short-circuiting failure of the capacitor 58 or 60.

The fuse portion 62 is positioned on a high-potential side of the capacitor 58. The potential sensing portion 41 senses the potential of the connection point 66 positioned between the capacitor 58 and the fuse portion 62. For this reason, a blowout of the fuse portion 62 causes a fall in a potential that is sensed by the potential sensing portion 41. This enables the control device 34 to sense the blowout of the fuse portion 62.

Similarly, the fuse portion 64 is positioned on a high-potential side of the capacitor 60. The potential sensing portion 42 senses the potential of the connection point 68 positioned between the capacitor 60 and the fuse portion 64. For this reason, a blowout of the fuse portion 64 causes a fall in a potential that is sensed by the potential sensing portion 42. This enables the control device 34 to sense the blowout of the fuse portion 64. It should be noted that a part of the wiring 65 is hereinafter sometimes referred to as the wiring 164. The wiring 164 is a part between the connection point 56 and the connection point 68.

When a blowout of the fuse portion 62 has been sensed, the control device 34 reduces a current flowing through the first switching element 18. Specifically, when the blowout of the fuse portion 62 has been sensed, the control device 34 outputs the output voltage V_{OUT} in accordance with the aforementioned protection mode characteristic 112. The solid line of the graph shown in FIG. 4 represents the protection mode characteristic 112. The protection mode characteristic 112 shows a relationship between the level of the target voltage signal S_{TG} and the magnitude of the output voltage V_{OUT} at a time when a blowout of the fuse portion 62 has been sensed. In the protection mode characteristic 112, as in the standard mode characteristic 110, the target voltage signal S_{TG} and the magnitude of the output voltage V_{OUT} are proportional to each other. However, when the level of the target voltage signal S_{TG} exceeds a certain value, the magnitude of the output voltage V_{OUT} becomes constant at an upper-limit value L₁. That is, in the protection mode characteristic 112, as compared with the standard mode characteristic 110, the magnitude of the output voltage V_{OUT} is smaller. The upper-limit value L₁ of the protection mode characteristic 112 is appropriately determined so that the magnitude of the output voltage V_{OUT} takes on a voltage value at which the destruction of the first switching element 18 by a surge voltage can be suppressed.

In the DC-DC converter 2 of the present embodiment, a current flowing through the first switching element 18 is reduced when it is determined that the fuse portion 62 has blown out to cause the capacitor 58 to lose the effect of reducing a surge voltage. This makes it possible to pass a current through the first switching element 18 while reducing a surge voltage that is applied to the first switching element 18.

Similarly, upon sensing a blowout of the fuse portion 64, the control device 34 reduces a current flowing through the second switching element 20.

An example of a correspondence relationship between claims 1 and 2 and Embodiment 1 is described. The connection point 52 is an example of a “first end” in the claims. The connection point 24 is an example of a “second end” in the claims. The wiring 19 is an example of a “first wiring” in the claims. The connection point 52 is an example of a “third end” in the claims. The connection point 56 is an example of a “fourth end” in the claims. The wiring 63 is an example of a “second wiring” in the claims.

Another example of a correspondence relationship between claims 1 and 2 and Embodiment 1 is described. The connection point 24 is an example of a “first end” in the claims. The connection point 26 is an example of a “second end” in the claims. The wiring 21 is an example of a “first wiring” in the claims. The connection point 56 is an example of a “third end” in the claims. The connection point 54 is an example of a “fourth end” in the claims. The wiring 65 is an example of a “second wiring” in the claims.

A correspondence relationship between claims 3, 4, and 7 and Embodiment 1 is described. The connection point 24 is an example of a “first connection point” in the claims. Further, the connection point 26 is an example of a “second connection point” in the claims. The wiring 19 is an example of a “third wiring” in the claims. The connection point 52 is an example of a “third connection point” in the claims. The wiring 63 and the wiring 25 are an example of a “fourth wiring” in the claims.

A correspondence relationship between claims 3, 5, and 7 and Embodiment 1 is described. The connection point 24 is an example of a “first connection point” in the claims. Further, the connection point 26 is an example of “second connection point” in the claims. The wiring 21 is an example of a “third wiring” in the claims. The connection point 54 is an example of a “fourth connection point” in the claims. The wiring 25 and the wiring 65 are an example of a “fourth wiring” in the claims.

### Embodiment 2

In a DC-DC converter 202 of Embodiment 2, a connection point 86 is provided on the input/output line 14. The connection point 86 is positioned on an output terminal 10 side of the first switching element 18. Further, the connection point 86 is positioned between the first switching element 18 and the connection point 55. A connection point 88 is provided on the reference potential line 16. The connection point 88 is positioned on an output reference terminal 12 side of the connection point 26. The connection point 88 is positioned between the connection point 26 and the connection point 58. A wiring 83 connects the connection point 86 and the connection 88. That is, the wiring 83 is set in parallel to the first switching element 18 and the second switching element 20. A capacitor 80 is set on the wiring 83. In other words, the capacitor 80 is set in parallel to the first switching element 18 and the second switching element 20.

A fuse portion 82 is provided on the wiring 83. The fuse portion 82 is positioned on a connection point 86 side of the capacitor 80. A connection point 84 is provided between the fuse portion 82 and the capacitor 80. The DC-DC converter 202 includes a potential sensing portion 48. The potential sensing section 48 senses a potential of the connection point 84.

In the DC-DC converter 202, as mentioned above, the capacitor 80 is set in parallel to the first switching element 18 and the second switching element 20. This reduces a surge voltage that is applied when the first switching element 18 and the second switching element 20 are turned on or off.

Further, at the time of a short-circuiting failure of the capacitor 80, the fuse portion 82 blows out to break off the wiring 83. This prevents an overcurrent from flowing through the DC-DC converter 202.

In the DC-DC converter 202, the fuse portion 82 is positioned on a high-potential side of the capacitor 80. The potential sensing portion 48 senses a potential of the connection point 84 positioned between the capacitor 80 and the fuse portion 82. For this reason, a blowout of the fuse portion 82 causes a fall in a potential that is sensed by the potential sensing portion 48. This makes it possible to sense the blowout of the fuse portion 82.

As with the control device 34 of Embodiment 1, when a blowout of the fuse portion 82 has been sensed, the control device 34 reduces a current flowing through the first switching element 18 and the second switching element 20.

A correspondence relationship between claims 1 and 2 and Embodiment 2 is described. The connection point 86 is an example of a “first end” in the claims. The connection point 24 is an example of a “second end” in the claims. The wiring 19 is an example of a “first wiring” in the claims. The connection point 86 is an example of a “third end” in the claims. The connection point 88 is an example of a “fourth end” in the claims. The wiring 83 is an example of a “second wiring” in the claims.

Another example of a correspondence relationship between claims 1 and 2 and Embodiment 2 is described. The connection point 24 is an example of a “first end.” in the claims. The connection point 26 is an example of a “second end” in the claims. The wiring 21 is an example of a “first wiring” in the claims. The connection point 86 is an example of a “third end” in the claims. The connection point 88 is an example of a “fourth end” in the claims. The wiring 83 is an example of a “second wiring” in the claims.

A correspondence relationship between claims 3, 6, and 7 and Embodiment 2 is described. The connection point 24 is an example of a “first connection point” in the claims. Further, the connection point 26 is an example of a “second connection point” in the claims. The wiring 21 is an example of a “third wiring” in the claims. The connection point 86 is an example of a “fifth connection point” in the claims. The connection point 88 is an example of a “sixth connection point” in the claims. The wiring 83 is an example of a “fourth wiring” in the claims.

The embodiments have been described in detail in the above. However, these are only examples and do not limit the claims. The technology described in the claims includes various modifications and changes of the concrete examples represented above.

The technical elements explained in the present description or drawings exert technical utility independently or in combination of some of them, and the combination is not limited to one described in the claims as filed. Moreover, the technology exemplified in the present description or drawings achieves a plurality of objects at the same time, and has technical utility by achieving one of such objects.

1. A semiconductor device, comprising:
a first wiring including a first end and a second end configured to receive a voltage lower than a voltage of the first end;
a second wiring including a third end connected to the first end, and a fourth end connected to the second end;
a switching element set on the first wiring;
a capacitor set on the second wiring;
a fuse portion set on the second wiring and positioned on a third end side of the capacitor;
a potential sensing portion connected to the second wiring between the fuse portion and the capacitor and configured to sense a potential of a connection point thereof; and
a control device configued to reduce a current flowing through the switching element and make the reduced current flow through the switching element when the second wiring is determined, from the potential sensed by the potential sensing portion, to have broken off.

2. (canceled)

3. A semiconductor device configured to receive an input voltage between an input terminal and an input-side reference terminal and to output an output voltage from between an output terminal and an output-side reference terminal, the semiconductor device comprising:
an input/output line connecting the input terminal and the output terminal;
a reference potential line connecting the input-side reference terminal and the output-side reference terminal;
a first switching element set on the input/output line;
a reactor set on the input/output line and positioned on an input terminal side of the first switching element;
a third wiring connecting a first connection point and a second connection point, the first connection point being set on the input/output line and positioned between the reactor and the first switching element, and the second connection point being positioned on the reference potential line;
a second switching element set on the third wiring;
a fourth wiring connected in parallel to one of the first switching element and the second switching element;
a first capacitor set on the fourth wiring;
a first fuse portion set on the fourth wiring and positioned on a high potential side of the first capacitor; and
a potential sensing portion connected to the fourth wiring between the first fuse portion and the first capacitor, and configured to sense a potential of a connection point thereof.

4. A semiconductor device of claim 3, wherein
the input/output line includes a third connection point positioned on an output terminal side of the first switching element, and
the fourth wiring connects the third connection point and the first connection point.

5. A semiconductor device of claim 3, wherein
the reference potential line includes a fourth connection point positioned on an output-side reference terminal side of the second connection point, and
the fourth wiring connects the first connection point and the fourth connection point.

6. A semiconductor device of claim 3, wherein
the input/output line includes a fifth connection point positioned on an output terminal side of the first switching element,
the reference potential line includes a sixth connection point positioned on an output-side reference terminal side of the second connection point, and
the fourth wiring connects the fifth connection point and the sixth connection point.

7. A semiconductor device of claim 3, further comprising a control device configured to reduce a current flowing through a switching element connected in parallel to the fourth wiring when the fourth wiring is determined, from the potential sensed by the potential sensing portion, to have broken off.
